(19) United States
(12) Patent Application Publication
(10) Pub. No.: US 2020/0176609 A1
(43) Pub. Date: Jun. 4, 2020

(54) FLASH MEMORIES AND METHODS FOR FORMING THE SAME

(71) Applicant: Vanguard International Semiconductor Corporation, Hsinchu (TW)

(72) Inventors: Ankit KUMAR, Ranchi (IN); Chia-Hao LEE, New Taipei City (TW)

(73) Assignee: Vanguard International Semiconductor Corporation, Hsinchu (TW)

(21) Appl. No.: 16/204,868

(22) Filed: Nov. 29, 2018

(51) Int. Cl. H01L 29/788; H01L 27/11521; H01L 29/423; H01L 29/49; H01L 29/66; H01L 21/28; H01L 21/3213; H01L 21/311

(52) U.S. Cl. CPC H01L 29/7881; H01L 27/11521; H01L 29/42324; H01L 29/4916; H01L 21/31144; H01L 21/28273; H01L 21/32135; H01L 21/32139; H01L 29/66825

(57) ABSTRACT

A flash memory is provided. The flash memory includes a semiconductor substrate, a floating gate structure on the semiconductor substrate, an inter-gate dielectric layer covering sidewalls and a top surface of the floating gate structure, and a control gate on the inter-gate dielectric layer. The floating gate structure includes a floating gate dielectric layer on the semiconductor substrate, a pair of dielectric spacers on the floating gate dielectric layer, wherein the pair of dielectric spacers have sloped sidewalls that face each other, and a floating gate on the floating gate dielectric layer and between the pair of dielectric spacers. The floating gate has a pair of tips over the respective sloped sidewalls of the pair of dielectric spacers.

### BACKGROUND

### Technical Field

The disclosure relates to flash memories and methods for forming the same.

### Description of the Related Art

A flash memory is a kind of non-volatile memory (NVM). Generally, a flash memory comprises two gates. The first gate is a floating gate (FG) for data storage, and the second gate is a control gate for data input/output. The floating gate is placed under the control gate and “floats”. Floating refers to isolating the floating gate and surrounding it with insulating materials for preventing charge loss. The control gate is connected to a word line (WL) for device control. One advantage of flash memories is block-by-block erasing. Flash memory is widely used in enterprise servers, storage and networking technology, and a wide range of consumer electronic products, such as USB flash drives, mobile phones, digital cameras, tablet computers, PC cards in notebook computers, and embedded controllers, for example.

There are several kinds of non-volatile memory available in the market, such as flash memory, electrically erasable programmable read-only memory (EEPROM) and multi-time programmable (MTP) non-volatile memory. However, embedded flash (e-flash) memory and especially embedded split-gate flash memory shows dominance over other non-volatile memory technologies.

Although existing flash memories and methods for manufacturing the same have been adequate for their intended purposes, they have not been entirely satisfactory in all respects. Therefore, up to the present, there are still some problems to be overcome in regards to the technologies of flash memories.

### BRIEF SUMMARY OF THE DISCLOSURE

Some embodiments of the disclosure provide a flash memory. The flash memory includes a semiconductor substrate, a floating gate structure on the semiconductor substrate, an inter-gate dielectric layer covering sidewalls and a top surface of the floating gate structure, and a control gate on the inter-gate dielectric layer. The floating gate structure includes a floating gate dielectric layer on the semiconductor substrate, a pair of dielectric spacers on the floating gate dielectric layer, wherein the pair of dielectric spacers have sloped sidewalls that face each other, and a floating gate on the floating gate dielectric layer and between the pair of dielectric spacers, wherein the floating gate has a pair of tips over the respective sloped sidewalls of the pair of dielectric spacers.

Some embodiments of the disclosure provide a method for manufacturing a flash memory. The method includes providing a semiconductor substrate; forming a mask layer on the semiconductor substrate, wherein the mask layer has an opening exposing a portion of the semiconductor substrate; forming a floating gate structure in the opening; removing the mask layer; forming an inter-gate dielectric layer covering sidewalls and a top surface of the floating gate structure; and forming a control gate on the inter-gate dielectric layer. The step of forming the floating gate structure in the opening includes forming a floating gate dielectric layer on the semiconductor substrate and a pair of dielectric spacers on opposite sidewalls of the opening and on the floating gate dielectric layer, and forming a floating gate in the opening, wherein the floating gate is disposed on the floating gate dielectric layer and between the pair of dielectric spacers, and wherein the floating gate has a pair of tips over the respective sloped sidewalls of the pair of dielectric spacers.

A detailed description is given in the following embodiments with reference to the accompanying drawings.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1 to 9 are cross-sectional views illustrating intermediate stages of an example method for forming the flash memory of FIG. 9 in accordance with some embodiments.

FIGS. 10 to 11 are cross-sectional views illustrating intermediate stages of another example method for forming a flash memory of FIG. 11 in accordance with some embodiments.

### DETAILED DESCRIPTION OF THE DISCLOSURE

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first component over or on a second component in the description that follows may include embodiments in which the first and second components are formed in direct contact, and may also include embodiments in which additional components may be formed between the first and second components, such that the first and second components may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that additional operations can be provided before, during, and after the method, and some of the operations described can be replaced or eliminated for other embodiments of the method.

The terms “about”, “approximately”, and “substantially” used herein generally refer to a value of an error or a range within 40 percent, preferably within 20 percent, and more preferably within 10 percent, within 5 percent, within 3 percent, within 2 percent, or within 1 percent. If there is no specific description, the mentioned values are regarded as an approximation that is the error or the range expressed as “about”, “approximate”, or “substantially”.

Some variations of the example methods and structures are described. A person having ordinary skill in the art will readily understand other modifications that may be made that are contemplated within the scope of other embodiments. Although method embodiments may be described in a particular order, various other method embodiments may be performed in any logical order and may include fewer or more steps than what is described herein. In some figures, some reference numbers of components or features illustrated therein may be omitted to avoid obscuring other components or features; this is for ease of depicting the figures.

Embodiments of flash memories and methods for forming the same are provided, especially an embedded split-gate flash memory. In some embodiments of the present disclosure, a pair of dielectric spacers is used to create a floating gate with a pair of sharp tips. The pair of sharp tips may improve the performance of the split-gate flash memory because the erase efficiency of the device is dependent on the sharpness of the tips. A method for forming the flash memory according to an embodiment of the present disclosure will be discussed in the following of the present disclosure.

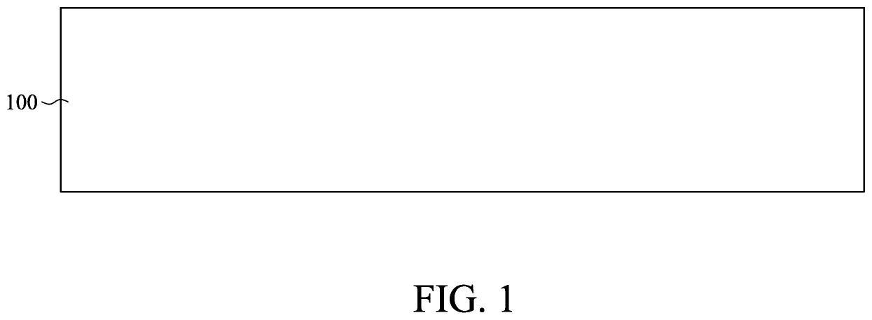

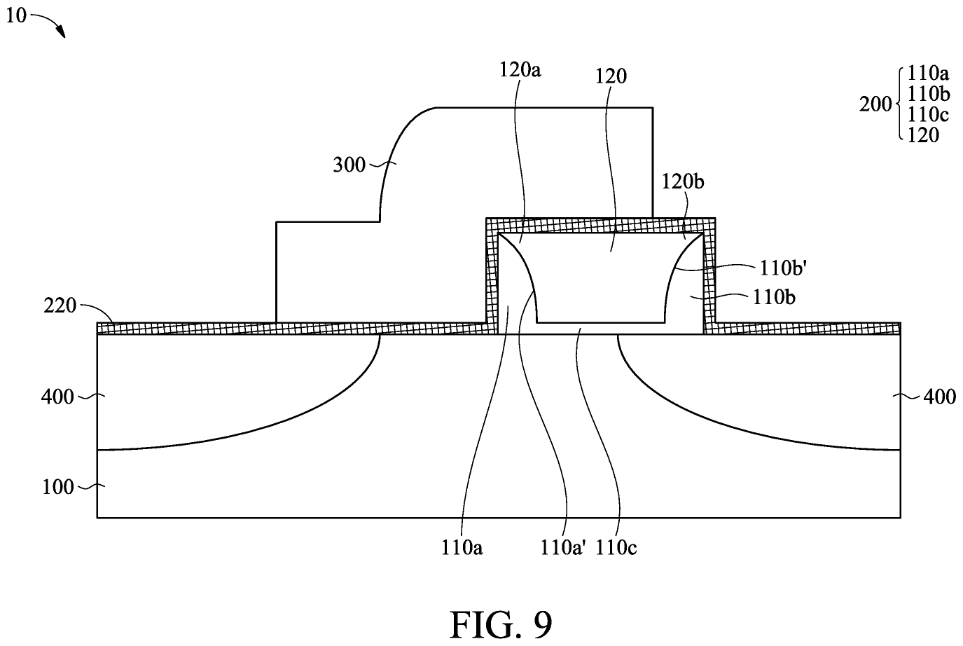

FIGS. 1 to 9 are cross-sectional views illustrating intermediate stages of an exemplary method for forming the flash memory 10 of FIG. 9 in accordance with some embodiments.

FIG. 1 illustrates an initial step of a method for forming the flash memory 10 according to an embodiment of the present disclosure. As shown in FIG. 1, a semiconductor substrate 100 is provided. The semiconductor substrate 100 may be or include a bulk semiconductor substrate, a semiconductor-on-insulator (SOI) substrate, or the like, which may be doped (e.g., with a p-type or an n-type dopant) or undoped. Generally, an SOI substrate comprises a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the semiconductor substrate may include an elemental semiconductor including silicon (Si) or germanium (Ge); a compound semiconductor including silicon carbide, gallium arsenic, gallium phosphide, indium phosphide, indium arsenide, or indium antimonide; an alloy semiconductor including SiGe, GaAsP, AlInAs, AlGaAs, GaInAs, GaInP, or GaInAsP; or a combination thereof.

In some embodiments, the semiconductor substrate 100 is a p-type silicon substrate. For example, the dopant of the p-type silicon substrate 100 may include boron, aluminum, gallium, indium, another applicable dopant, or a combination thereof, and a dopant concentration of the p-type silicon substrate 100 may be 5×10¹⁴ cm⁻³ to 5×10¹⁶ cm⁻³. In other embodiments, the semiconductor substrate 100 may be an n-type silicon substrate. For example, the dopant of the n-type silicon substrate 100 may include arsenic, phosphorus, antimony, another applicable dopant, or a combination thereof, and a dopant concentration of the n-type silicon substrate 100 may be 5×10¹⁴ cm⁻³ to 5×10¹⁶ cm⁻³. In the interests of simplicity and clarity, the present embodiment uses a p-type silicon substrate 100 as an example, but the present disclosure is not limited thereto.

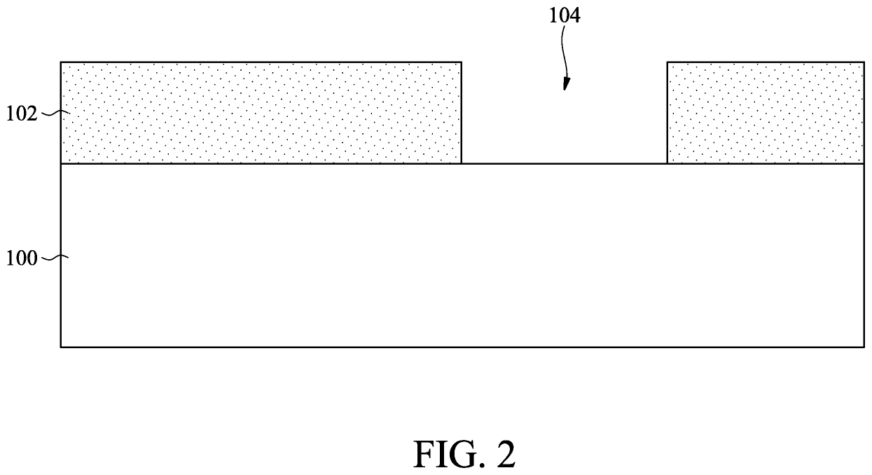

Next, as shown in FIG. 2, a mask layer 102 is formed on the semiconductor substrate 100, and an opening 104 is formed in the mask layer 102. As shown in FIG. 2, a portion of the semiconductor substrate 100 is exposed by the opening 104, and the opening 104 is formed to define the location where a floating gate structure is planned to be formed subsequently.

In some embodiments, the mask layer 102 may include nitride, such as silicon nitride, silicon oxynitride, another applicable material, or a combination thereof. For example, the mask layer 102 may be formed by a low pressure chemical vapor deposition process, a plasma enhanced chemical vapor deposition process, another applicable process, or a combination thereof. For example, the thickness of the mask layer 102 may be 0.1 μm to 1 μm, but it is not limited thereto.

In some embodiments, the opening 104 may be formed in the mask layer 102 by a patterning process. For example, the patterning process may include a lithography process (e.g., photoresist coating, soft baking, mask aligning, exposure, post-exposure baking, developing photoresist, another applicable process, or a combination thereof), an etching process (e.g., a wet etching process, a dry etching process, another applicable process, or a combination thereof), another applicable process, or a combination thereof. In some embodiments, a patterned photoresist layer (not shown) having an opening corresponding to the opening 104 may be formed on the mask layer 102 by a lithography process, and then an etching process may be performed to remove a portion of the mask layer 102 exposed by the opening of the patterned photoresist layer (not shown) to form the opening 104 in the mask layer 102.

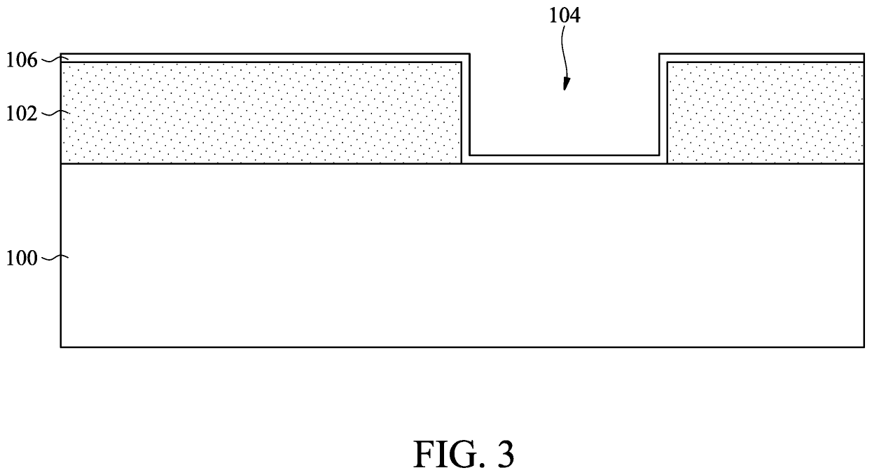

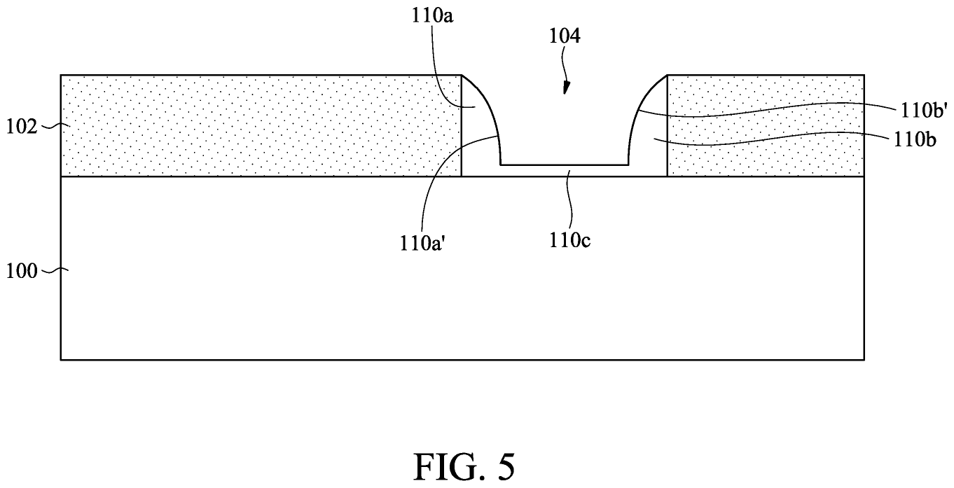

FIG. 3 illustrates the formation of a first dielectric layer 106. The first dielectric layer 106 is conformally formed over the mask layer 102, and thus the first dielectric layer 106 is along the opposite sidewalls and a bottom surface of the opening 104. The first dielectric layer 106 on the bottom surface of the opening 104 will serve as a floating gate dielectric layer 110c, and the first dielectric layer 106 on the opposite sidewalls of the opening 104 will serve as a part of dielectric spacers 110a and 110b in the subsequent processes (not illustrated in FIG. 3 but illustrated and described below with respect to FIG. 5).

In some embodiments, the first dielectric layer 106 may be silicon oxide, silicon nitride, silicon oxynitride, high-k dielectric material, any other suitable dielectric material, or a combination thereof. The high-k dielectric material may be metal oxide, metal nitride, metal silicide, transition metal oxide, transition metal nitride, transition metal silicide, metal oxynitride, metal aluminate, zirconium silicate, or zirconium aluminate. For example, the high-k dielectric material may be LaO, AlO, ZrO, TiO, Ta₂O₅, Y₂O₃, SrTiO₃(STO), BaTiO₃(BTO), BaZrO, HfO₂, HfO₃, HfZrO, HfLaO, HfSiO, HfSiON, LaSiO, AlSiO, HfTaO, HfTiO, HfTaTiO, HfAlON, (Ba,Sr)TiO₃(BST), Al₂O₃, any other suitable high-k dielectric material, or a combination thereof. In some embodiments, the first dielectric layer 106 may be formed by a chemical vapor deposition process (e.g., a plasma enhanced chemical vapor deposition (PECVD) process, or a metalorganic chemical vapor deposition (MOCVD) process), an atomic layer deposition (ALD) process (e.g., a plasma enhanced atomic layer deposition (PEALD) process), another applicable process, or a combination thereof.

In some embodiments, a thickness of the first dielectric layer 106 may be 50 Å to 300 Å, but it is not limited thereto.

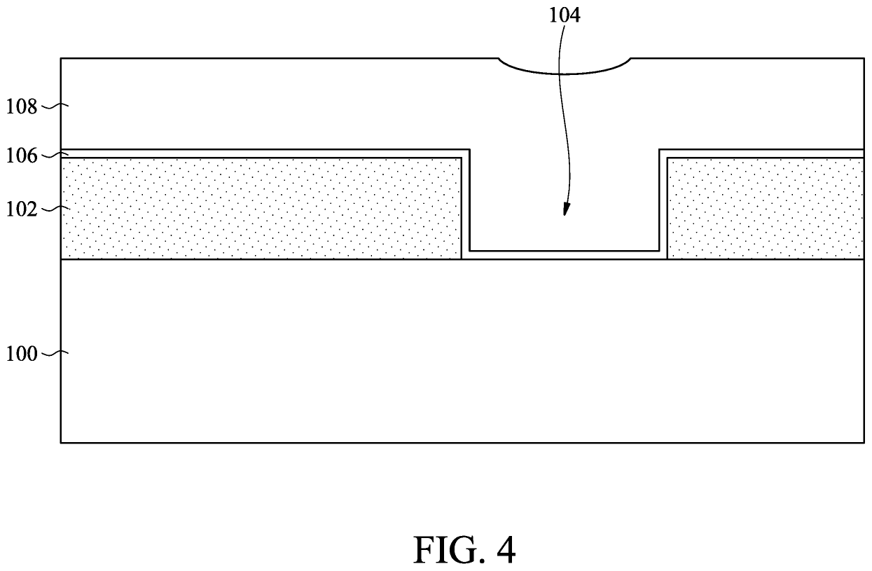

Next, as shown in FIG. 4, a second dielectric layer 108 is formed on the first dielectric layer 106, wherein the second dielectric layer 108 overfills the opening 104. Portions of the second dielectric layer 108 will serve as a part of dielectric spacers 110a and 110b in the subsequent processes (not illustrated in FIG. 4 but illustrated and described below with respect to FIG. 5). The materials of the second dielectric layer 108 may be similar to the materials of the first dielectric layer 106, and therefore are not repeated here. In some embodiments, the second dielectric layer 108 and the first dielectric layer 106 may be formed of the same material. In other embodiments, the second dielectric layer 108 and the first dielectric layer 106 may be formed of different materials.

In some embodiments, the second dielectric layer 108 may be formed by a chemical vapor deposition process (e.g., a plasma enhanced chemical vapor deposition (PECVD) process, or a metalorganic chemical vapor deposition (MOCVD) process), an atomic layer deposition (ALD) process (e.g., a plasma enhanced atomic layer deposition (PEALD) process), spin-on-glass (SOG) process, another applicable process, or a combination thereof.

FIG. 5 illustrates the formation of the floating gate dielectric layer 110c and the pair of dielectric spacer 110a and 110b. In some embodiments, an anisotropic etching back process is performed on the first dielectric layer 106 and the second dielectric layer 108 to remove portions of the first dielectric layer 106 and the second dielectric layer 108. After the anisotropic etching back process, the first dielectric layer 106 on the bottom surface of the opening 104 serves as the floating gate dielectric layer 110c, and the first dielectric layer 106 on the opposite sidewalls of the opening 104 and a remaining of the second dielectric layer 108 serve as the pair of dielectric spacers 110a and 110b, as shown in FIG. 5.

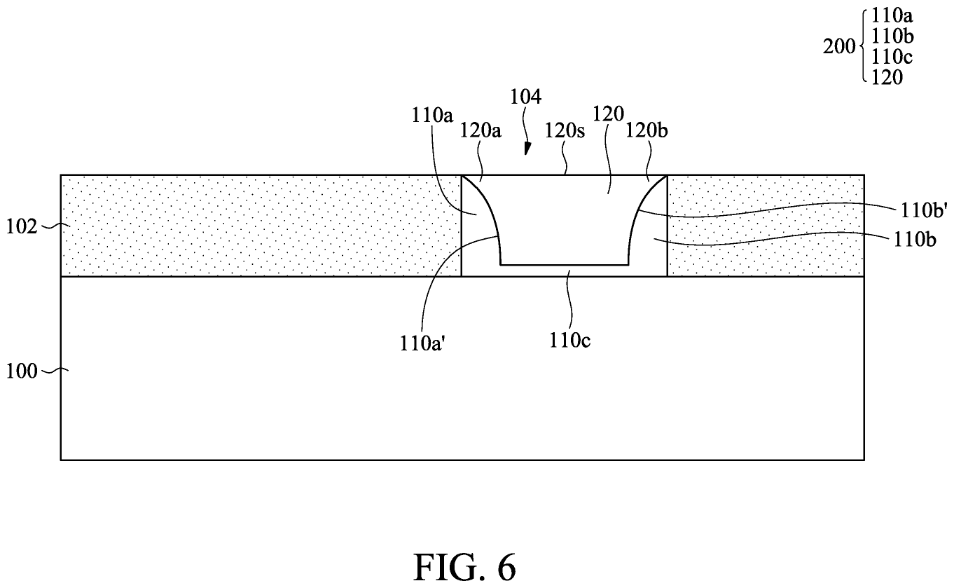

The pair of dielectric spacers 110a and 110b will be used to create a floating gate 120 with a pair of tips 120a and 120b (not illustrated in FIG. 5 but illustrated and described below with respect to FIG. 6) in the subsequent process, wherein the pair of tips 120a and 120b is over the pair of dielectric spacers 110a and 110b respectively.

As shown in FIG. 5, in some embodiments, after the anisotropic etching back process, the dielectric spacer 110a may have a sloped sidewall 110a′, and the dielectric spacer 110b may have a sloped sidewall 110b′ facing the sloped sidewall 110a′. The pair of sloped sidewalls 110a′ and 110b′ has a benefit of increasing the sharpness of the tips 120a and 120b (see FIG. 6).

In some embodiments, after the anisotropic etching back process, the pair of dielectric spacer 110a and 110b may be the same height as the mask layer 102, as shown in FIG. 5. In other words, topmost portions of the pair of dielectric spacers 110a and 110b and a top surface of the mask layer 102 are on the same level, which also helps to improve the sharpness of the tips 120a and 120b (see FIG. 6).

In some embodiments, the anisotropic etching back process may be a dry etching process, such as a plasma etching process, a reactive ion etching process, another applicable process, or a combination thereof.

FIG. 6 illustrates the formation of the floating gate 120. In some embodiments, the floating gate 120 is formed to fill the opening 104, wherein the floating gate 120 is disposed on the floating gate dielectric layer 110c and between the pair of dielectric spacers 110a and 110b. The floating gate 120, the pair of dielectric spacers 110a and 110b, and the floating gate dielectric layer 110c together constitute a floating gate structure 200. Furthermore, the floating gate 120 has the pair of tips 120a and 120b over the respective sloped sidewalls 110a′ and 110b′ of the pair of dielectric spacers 110a and 110b, as shown in FIG. 6. The pair of tips 120a and 120b of the floating gate 120 may increase the current flow between the floating gate 120 and a control gate to be formed in the subsequent processes, thereby improving the performance of the flash memory (e.g., reducing the erasing time).

In some embodiments, the material of the floating gate 120 includes poly-silicon. In other embodiments, the material of the floating gate 120 may include metals (e.g., tungsten, titanium, aluminum, copper, molybdenum, nickel, platinum, the like, or a combination thereof), metal alloys, metal-nitrides (e.g., tungsten nitride, molybdenum nitride, titanium nitride, and tantalum nitride, the like, or a combination thereof), metal-silicides (e.g., tungsten silicide, titanium silicide, cobalt silicide, nickel silicide, platinum silicide, erbium silicide, the like, or a combination thereof), metal-oxides (e.g., ruthenium oxide, indium tin oxide, the like, or a combination thereof), another applicable material, or a combination thereof.

For example, the floating gate 120 may be formed by a chemical vapor deposition process (e.g., a low pressure chemical vapor deposition process, or a plasma enhanced chemical vapor deposition process), a physical vapor deposition process (e.g., a vacuum evaporation process, or a sputtering process), another applicable process, or a combination thereof. In some embodiments, the material of the floating gate 120 may be formed to overfill the opening 104, and then an etch back or a planarization process (e.g., chemical-mechanical-polishing (CMP) process) may be performed to remove excess portions of the material of the floating gate 120 outside the opening 104 to form the floating gate 120 in the opening 104.

In some embodiments, the floating gate 120 may have a planar top surface 120s which is level with the topmost portions of the pair of dielectric spacers 110a and 110b after performing the planarization process or the etch back process, as shown in FIG. 6. In some embodiments, the floating gate 120 together with the pair of dielectric spacers 110a and 110b has a rectangular shape in a cross-sectional view, as shown in FIG. 6.

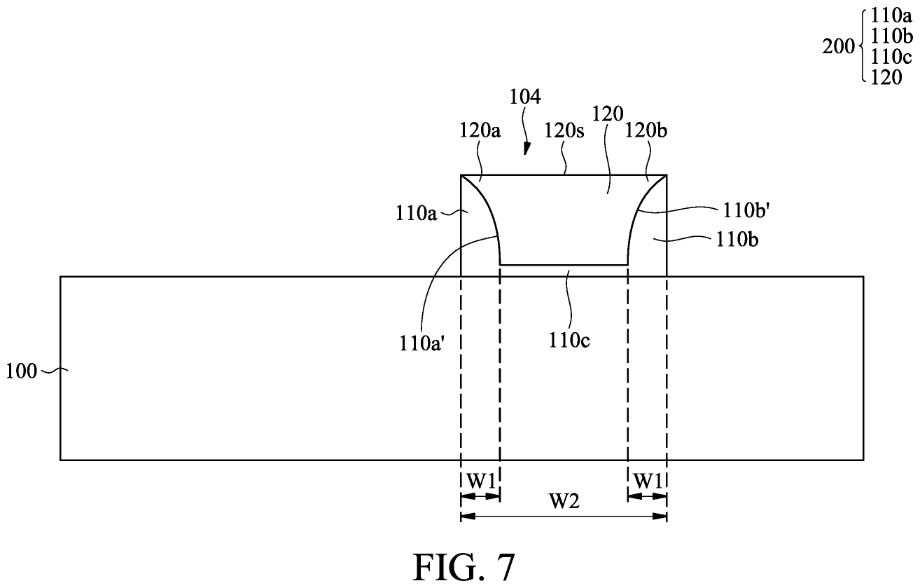

Next, as shown in FIG. 7, an etching process (e.g., a wet etching process, a dry etching process, another applicable process, or a combination thereof) is performed to selectively remove the mask layer 102 from the substrate, while the floating gate structure 200 is remained on the semiconductor substrate 100 after the etching process.

As shown in FIG. 7, each of the pair of dielectric spacers 110a and 110b may have a bottom width W1, and floating gate structure 200 may have a bottom width W2, wherein W2 is larger than W1. When W1 is smaller, the erase efficiency of the device is better due to the sharper tips 120a and 120b.

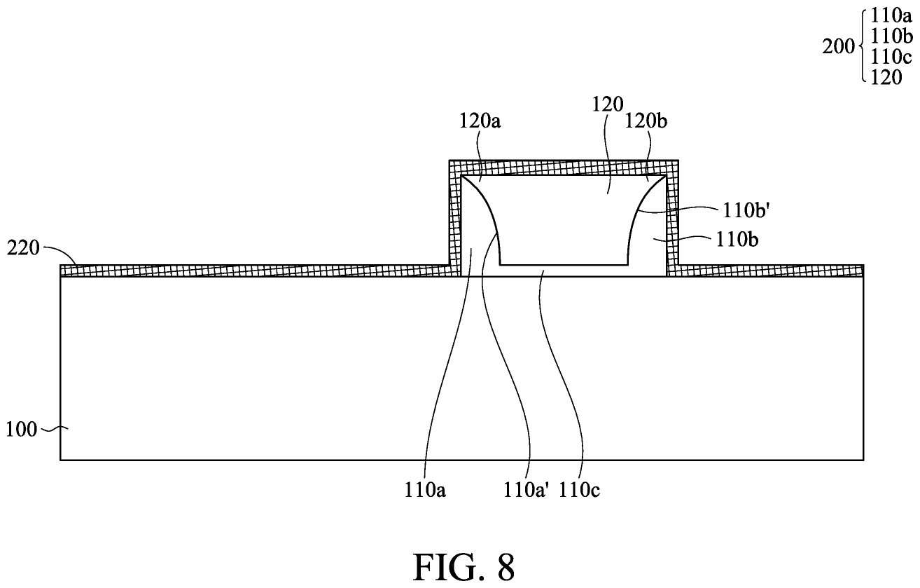

Then, as shown in FIG. 8, an inter-gate dielectric layer 220 is conformally formed on the substrate 100 and the floating gate structure 200. In some embodiments, the inter-gate dielectric layer 220, the pair of dielectric spacers 110a and 110b, and the floating gate dielectric layer 110c completely encapsulate the floating gate 120.

In the embodiment illustrated, the inter-gate dielectric layer 220 may include silicon oxide. The silicon oxide may be formed by an oxidation process, a chemical vapor deposition process, another applicable process, or a combination thereof. For example, the oxidation process may include a dry oxidation process (e.g., Si+O₂→SiO₂), a wet oxidation process (e.g., Si+2H₂O→SiO₂+2H₂), or a combination thereof.

In other embodiments, the inter-gate dielectric layer 220 may include a high-k dielectric material. The high-k dielectric material may include HfO₂, LaO, AlO, ZrO, TiO, Ta₂O₅, Y₂O₃, SrTiO₃, BaTiO₃, BaZrO, HfZrO, HfLaO, HfTaO, HfSiO, HfSiON, HfSiO, LaSiO, AlSiO, (Ba, Sr)TiO₃, Al₂O₃, another applicable high-k dielectric material, or a combination thereof. For example, the high-k dielectric layer may be formed by a chemical vapor deposition process (e.g., a plasma enhanced chemical vapor deposition process, or a metalorganic chemical vapor deposition process), an atomic layer deposition process (e.g., a plasma enhanced atomic layer deposition process), a physical vapor deposition process (e.g., a vacuum evaporation process, or a sputtering process), another applicable process, or a combination thereof.

In some embodiments, a thickness of the inter-gate dielectric layer 220 may be 50 Å to 250 Å μm, but it is not limited thereto.

FIG. 9 illustrates the formation of a control gate 300. In some embodiments, the control gate 300 is formed on the inter-gate dielectric layer 220. More specifically, the control gate 300 covers the dielectric spacer 110a, and the dielectric spacer 110b is not covered by the control gate 300, as shown in FIG. 9. It should be noted that the control gate 300 is separated from the floating gate structure 200 by the inter-gate dielectric layer 220. In the embodiment illustrated, the control gate 300 includes poly-silicon. In other embodiments, the control gate 300 may include metals (e.g., tungsten, titanium, aluminum, copper, molybdenum, nickel, platinum, the like, or a combination thereof), metal alloys, metal-nitrides (e.g., tungsten nitride, molybdenum nitride, titanium nitride, and tantalum nitride, the like, or a combination thereof), metal-silicides (e.g., tungsten silicide, titanium silicide, cobalt silicide, nickel silicide, platinum silicide, erbium silicide, the like, or a combination thereof), metal-oxides (e.g., ruthenium oxide, indium tin oxide, the like, or a combination thereof), another applicable material, or a combination thereof.

In some embodiments, the control gate 300 may be formed by a deposition process followed by a patterning process. The deposition process may include chemical vapor deposition process (e.g., a low pressure chemical vapor deposition process, or a plasma enhanced chemical vapor deposition process), a physical vapor deposition process (e.g., a vacuum evaporation process, or a sputtering process), another applicable process, or a combination thereof. The patterning process may include an etching process.

FIG. 9 illustrates the formation of a pair of source/drain regions 400 as well. In some embodiments, the pair of source/drain regions 400 is formed by implanting ions into the semiconductor substrate 100. The floating gate structure 200 and the control gate 300 are located between the pair of source/drain regions 400.

In this embodiment, the semiconductor substrate 100 is a p-type substrate, and the pair of source/drain regions 400 is formed by implanting n-type dopants, such as phosphorous (P) or arsenic (As), in the semiconductor substrate 100. In other embodiments, the semiconductor substrate 100 is an n-type substrate, and the pair of source/drain regions 400 is formed by implanting p-type dopants, such as boron (B), in the semiconductor substrate 100. The conductivity type of the semiconductor substrate 100 is opposite to the conductivity type of the pair of source/drain regions 400.

As shown in FIG. 9, the flash memory 10 includes the semiconductor substrate 100, the floating gate structure 200 on the semiconductor substrate 100, the inter-gate dielectric layer 220 covering the sidewalls and the top surface of the floating gate structure 200, and the control gate 300 on the inter-gate dielectric layer 220. The floating gate structure 200 includes the floating gate dielectric layer 110c on the semiconductor substrate 100, the pair of dielectric spacers 110a and 110b on the floating gate dielectric layer 110c, wherein the pair of dielectric spacers 110a and 110b have sloped sidewalls 110a′ and 110b′ facing each other, and the floating gate 120 on the floating gate dielectric layer 110c and between the pair of dielectric spacers 110a and 110b, wherein the floating gate 120 has the pair of tips 120a and 120b over the respective sloped sidewalls 110a′ and 110b′ of the pair of dielectric spacers 110a and 110b. The erase efficiency of the device is dependent on the sharpness of the pair of tips 120a and 120b. The sloped sidewalls 110a′ and 110b′ have a benefit of increasing the sharpness of the pair of tips 120a and 120b, thereby improving the performance of the flash memory 10.

In some embodiments, the topmost portions of the pair of dielectric spacers 110a and 110b and the top surface of the mask layer 102 are on the same level, which also helps to increase the sharpness of the tips 120a and 120b, thus the performance of the flash memory 10 may be further improved.

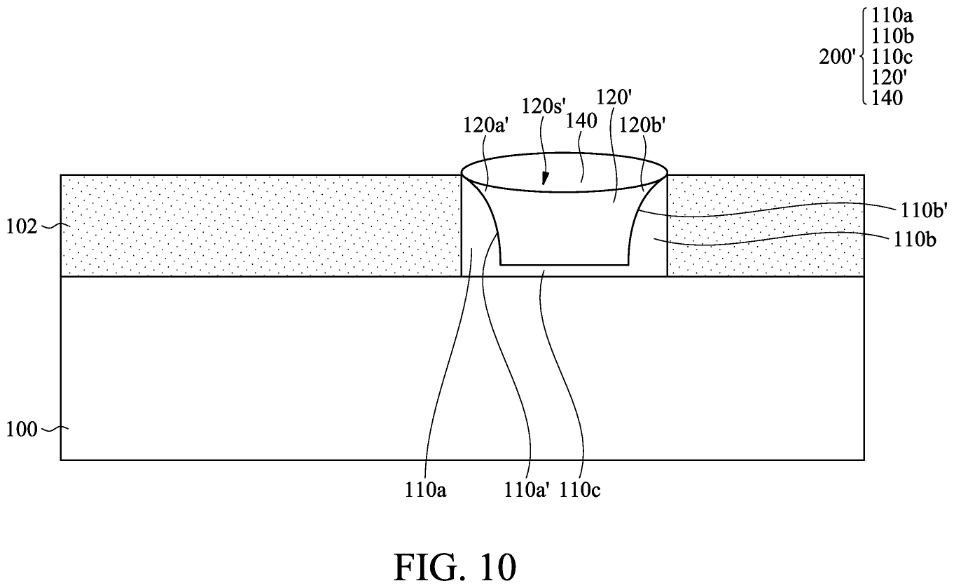

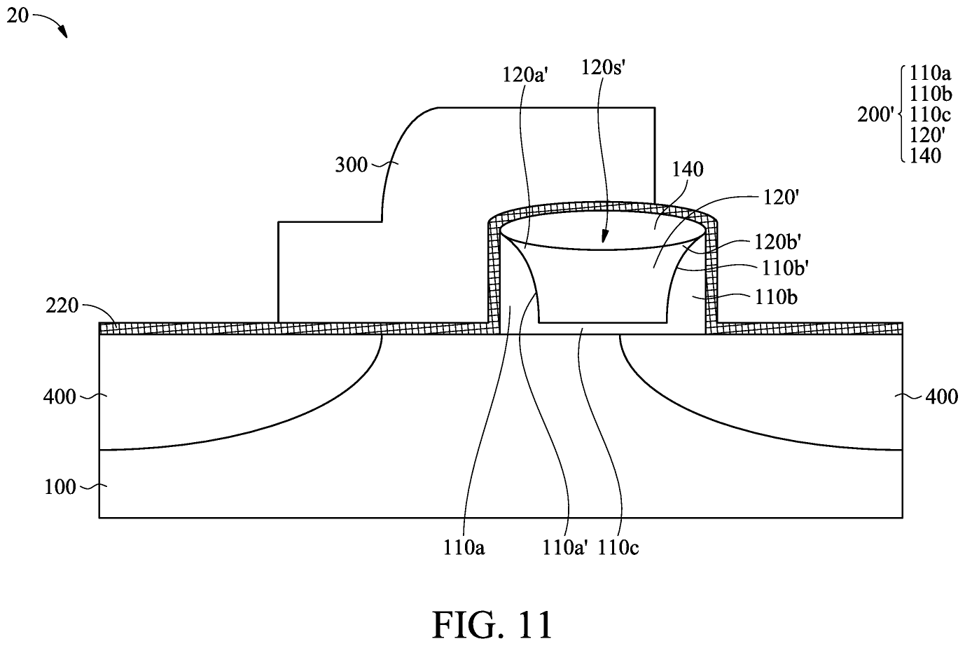

FIGS. 10 to 11 are cross-sectional views illustrating intermediate stages of another exemplary method for forming a flash memory 20 of FIG. 11 in accordance with some embodiments. For the sake of clarity, similar or same elements and processes will be given the same reference numbers. For the purpose of brevity, the descriptions of these processes and devices are not repeated herein.

The flash memory 20 is similar to the flash memory 10, except that an additional oxide structure 140 is formed to further sharpen the tips of the floating gate. As a result, a floating gate 120′ has a concave top surface 120s′, and a pair of tips 120a′ and 120b′ of the floating gate 120′ of flash memory 20 is sharper than the pair of tips 120a and 120b of the flash memory 10 of FIG. 9.

Referring to FIG. 10, following the formation of the floating gate 120 as described in FIG. 6, an oxide structure 140 is formed on the top surface of the floating gate 120′ before removing the mask layer 102. As shown in FIG. 10, in some embodiments, an oxidation process is performed on the floating gate 120 to form the floating gate 120′ and the oxide structure 140 on the floating gate 120′, wherein the floating gate 120′ has the concave top surface 120s′, and topmost portions of the floating gate 120′ and topmost portions of the pair of dielectric spacers 110a and 110b are on the same level. The floating gate 120′ has the pair of tips 120a′ and 120b′ that is sharper than the pair of tips 120a and 120b of the flash memory 10 of FIG. 9, and thus the flash memory 20 to be formed in the subsequent processes may have better erase efficiency than the flash memory 10.

Then, the mask layer 102 is removed and a series of processes similar to the processes described in FIGS. 7 to 9 is performed on the structure illustrated in FIG. 10 to complete the flash memory 20 illustrated in FIG. 11.

As shown in FIG. 11, the flash memory 20 includes the semiconductor substrate 100, the floating gate structure 200′ on the semiconductor substrate 100, the inter-gate dielectric layer 220 covering sidewalls and a top surface of the floating gate structure 200′, and the control gate 300 on the inter-gate dielectric layer 220. The floating gate structure 200′ includes the floating gate dielectric layer 110c on the semiconductor substrate 100, the pair of dielectric spacers 110a and 110b on the floating gate dielectric layer 110c, wherein the pair of dielectric spacers 110a and 110b have sloped sidewalls 110a′ and 110b′ facing each other, and the floating gate 120′ on the floating gate dielectric layer 110c and between the pair of dielectric spacers 110a and 110b, wherein the floating gate 120′ has the pair of tips 120a′ and 120b′ over the respective sloped sidewalls 110a′ and 110b′ of the pair of dielectric spacers 110a and 110b. The sloped sidewalls 110a′ and 110b′ have a benefit of increasing the sharpness of the pair of tips 120a and 120b, thereby improving the performance of the flash memory 20.

In some embodiments, the topmost portions of the pair of dielectric spacers 110a and 110b and a top surface of the mask layer 102 are on the same level, which also helps to increase the sharpness of the tips 120a′ and 120b′, thus the performance of the flash memory 20 may be further improved.

In some embodiments, the floating gate structure 200′ further includes the oxide structure 140 between the floating gate 120′ and the inter-gate dielectric layer 220. In this embodiment, the floating gate 120′ has a concave top surface 120s′ which may further sharp the pair of tips 120a′ and 120b′. In this embodiment, topmost portions of the floating gate 120′ and topmost portions of the pair of dielectric spacers 110a and 110b are on the same level. As a result, the erase efficiency of the flash memory 20 may be further improved.

In summary, the flash memory according to embodiments of the present disclosure includes a pair of dielectric spacers which is used to create a floating gate with a pair of sharp tips. The pair of sharp tips may increase the current flow between the floating gate and the control gate, thereby improving the performance of the split-gate flash memory cell (e.g., reducing the erasing time).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A flash memory, comprising:
a semiconductor substrate;
a floating gate structure on the semiconductor substrate, comprising:
a floating gate dielectric layer on the semiconductor substrate;
a pair of dielectric spacers on the floating gate dielectric layer, wherein the pair of dielectric spacers have sloped sidewalls that face each other; and
a floating gate on the floating gate dielectric layer and between the pair of dielectric spacers, wherein the floating gate has a pair of tips over the respective sloped sidewalls of the pair of dielectric spacers;
an inter-gate dielectric layer covering sidewalls and a top surface of the floating gate structure; and
a control gate on the inter-gate dielectric.

2. The flash memory of claim 1, wherein the floating gate has a planar top surface.

3. The flash memory of claim 2, wherein the top surface of the floating gate and topmost portions of the pair of dielectric spacers are on the same level.

4. The flash memory of claim 2, wherein the floating gate together with the pair of dielectric spacers has a rectangular shape in a cross-sectional view.

5. The flash memory of claim 1, wherein the floating gate structure further comprises an oxide structure between the floating gate and the inter-gate dielectric layer.

6. The flash memory of claim 5, wherein the floating gate has a concave top surface.

7. The flash memory of claim 5, wherein topmost portions of the floating gate and topmost portions of the pair of dielectric spacers are on the same level.

8. The flash memory of claim 1, wherein the floating gate and the control gate comprise poly-silicon.

9. The flash memory of claim 1, wherein the inter-gate dielectric layer, the pair of dielectric spacers, and the floating gate dielectric layer completely encapsulate the floating gate.

10. A method for forming a flash memory, comprising:
providing a semiconductor substrate;
forming a mask layer on the semiconductor substrate, wherein the mask layer has an opening exposing a portion of the semiconductor substrate;
forming a floating gate structure in the opening, comprising:
forming a floating gate dielectric layer on the semiconductor substrate and a pair of dielectric spacers on opposite sidewalls of the opening and on the floating gate dielectric layer; and
forming a floating gate in the opening, wherein the floating gate is disposed on the floating gate dielectric layer and between the pair of dielectric spacers, and wherein the floating gate has a pair of tips over the respective sloped sidewalls of the pair of dielectric spacers;
removing the mask layer;
forming an inter-gate dielectric layer covering sidewalls and a top surface of the floating gate structure; and
forming a control gate on the inter-gate dielectric layer.

11. The method for forming a flash memory of claim 10, wherein forming the floating gate dielectric layer and the pair of dielectric spacers comprises:
conformally forming a first dielectric layer along the opposite sidewalls and a bottom surface of the opening;
forming a second dielectric layer on the first dielectric layer, wherein the second dielectric layer overfills the opening; and
performing an anisotropic etching back process on the first dielectric layer and the second dielectric layer, after the anisotropic etching back process, the first dielectric layer on the bottom surface of the opening serves as the floating gate dielectric layer, and the first dielectric layer on the opposite sidewalls of the opening and a remaining of the second dielectric layer serve as the pair of dielectric spacers.

12. The method for forming a flash memory of claim 10, wherein topmost portions of the pair of dielectric spacers and a top surface of the mask layer are on the same level.

13. The method for forming a flash memory of claim 10, wherein the pair of dielectric spacers have sloped sidewalls that face each other.

14. The method for forming a flash memory of claim 10, wherein the floating gate has a planar top surface.

15. The method for forming a flash memory of claim 14, wherein the top surface of the floating gate and topmost portions of the pair of dielectric spacers are on the same level.

16. The method for forming a flash memory of claim 10, wherein forming the floating gate structure further comprises performing a thermal oxidation process on the floating gate to form an oxide structure between the floating gate and the inter-gate dielectric layer.

17. The method for forming a flash memory of claim 16, wherein the floating gate has a concave top surface.

18. The method for forming a flash memory of claim 10, wherein the mask layer comprises nitride.

19. The method for forming a flash memory of claim 10, wherein the floating gate and the control gate comprise poly-silicon.

20. The method for forming a flash memory of claim 10, wherein the inter-gate dielectric layer, the pair of dielectric spacers, and the floating gate dielectric layer completely encapsulate the floating gate.
